(19) United States
(12) Patent Application Publication
(10) Pub. No.: US 2008/0176529 A1
(43) Pub. Date: Jul. 24, 2008

(54) SUPERREGENERATIVE SYSTEM

(75) Inventor: Henry SinKai Lau, Lexington, MA (US)

Correspondence Address: TROUTMAN SANDERS LLP, 600 PEACHTREE STREET , NE, ATLANTA, GA, 30308, US

(73) Assignee: Lexiwave Technology (Hong Kong), Limited, Hong Kong (CN)

(21) Appl. No.: 11/625,042

(22) Filed: Jan. 19, 2007

(51) Int. Cl. H04B 1/16; H03B 5/36

(52) U.S. Cl. 455/336; 331/107 A

(57) ABSTRACT

Methods and apparatuses for superregenerative system are disclosed, including an oscillator circuit for a superregenerative receiver. The oscillator circuit includes an RF oscillator, incorporating a self-biased transistor and a positive feedback circuit; and an external quench oscillator, for providing a quench signal to the RF oscillator; wherein the quench signal is coupled to the RF oscillator through a reversed-biased diode. The arrangement improves the performance of conventional superregenerative receivers by providing high selectivity and optimum receiver sensitivity, which is insusceptible to variations in supply voltage, temperature and device parameters.

### BACKGROUND OF THE INVENTION

1. Field of the Invention

The present invention relates generally to modulated wireless signal receivers and, in particular, to modulated wireless signal receivers with superregenerative oscillators.

2. Description of Related Art

Superregenerative receivers were invented by Edwin Howard Armstrong more than eighty years ago. Nowadays, millions of superregenerative receiver products are being sold each year. The application of superregenerative receivers includes garage door opener receiver, wireless security receiver, wireless doorbell and remote controller. One conventional design of superregenerative receiver uses a single transistor with an inductor and a capacitor to form a basic self-quench superregenerative receiver. However, such a design suffers from several performance problems such as center frequency drift with temperature variation, circuit component aging, and excessive receiver bandwidth.

The above problems can be overcome by incorporating a surface acoustic wave (SAW) device as a resonating element. Unfortunately, the higher the frequency selectivity of the SAW device is, the lower the quench frequency must be made in order to allow proper oscillation buildup. Furthermore, the quench frequency of such a SAW stabilized receiver changes with input signal level, which in turns further limits its maximum quench frequency. Since the receiver sensitivity is directly proportional to the quench frequency, it is desirable to make the quench frequency as high as feasible.

The externally-quenched SAW superregenerative receiver was thus developed to offer both high frequency stability and high receiver sensitivity. However, the receiver's performance is very sensitive to the external quench signal level as the DC operating point of the RF oscillator is biased directly by the quench voltage. Such dependency will make the receiver's sensitivity prone to changes due to supply voltage, temperature and device parameter variations.

Accordingly, a need yet exists for an improved design of superregenerative receiver with robustness to withstand variation in supply voltage, temperature and device parameters.

### BRIEF SUMMARY OF THE INVENTION

In accordance with a first preferred aspect of the invention, there is provided an oscillator circuit for a superregenerative receiver. The oscillator circuit can comprise an RF oscillator, comprising a self-biased transistor and a positive feedback circuit; and, an external quench oscillator, for providing quench signal to said RF oscillator; wherein said quench signal is coupled to said RF oscillator through a reversed-biased diode.

The transistor can be a bipolar transistor or an FET transistor.

The positive feedback circuit of said RF oscillator can comprise a lumped or distributed resonating network, or a SAW device.

In accordance with a further preferred aspect of the invention, there is provided a superregenerative receiver. The receiver comprises an oscillator circuit, comprising an RF oscillator, comprising a self-biased transistor and a positive feedback circuit; and an external quench oscillator for providing quench signal; wherein said quench signal is coupled to said RF oscillator through a reversed-biased diode; a low pass filter for filtering the output of said oscillator circuit; and a low-frequency amplifier for amplifying the output of said low pass filter.

The transistor can be a bipolar transistor or FET transistor.

The positive feedback circuit of said RF oscillator can comprise a lumped or distributed resonating network or a SAW device.

The modulated RF signal from the antenna is coupled to said RF oscillator at any of the three terminals of said transistor.

The receiver can further comprise a voltage comparator for comparing the output of said amplifier with a reference voltage to provide a demodulated digital signal.

The receiver can further comprise an audio amplifier for amplifying the output of said low-frequency amplifier to provide a demodulated audio signal.

According to a further preferred aspect of the invention, there is provided a method of detecting a modulated RF signal. The method comprises the steps of: providing an external quench signal of low frequency; providing an oscillator operating at radio frequency, said oscillator comprises a self-biased transistor and positive feedback circuit; coupling said quench signal to said RF oscillator through a reversed-biased diode; and coupling the modulated RF signal from the antenna to said RF oscillator at any of the three terminals of said transistor.

The method can further comprise the steps of: low pass filtering the output of said RF oscillator to provide filtered signal; and amplifying the filtered signal to provide an amplified signal.

The method can further comprise the step of comparing said amplified signal with reference voltage to provide demodulated digital signal.

The method can further comprise the step of amplifying said amplified signal with audio amplifier to provide demodulated audio signal.

### BRIEF DESCRIPTION OF THE DRAWINGS

One or more embodiments are described hereinafter, by way of example only, with reference to the accompanying drawings in which:

FIG. 1 is a block diagram of a superregenerative receiver in accordance with a preferred embodiment of the present invention; and

FIG. 2 is a schematic circuit diagram of the superregenerative receiver in FIG. 1.

### DETAILED DESCRIPTION OF PREFERRED EMBODIMENTS

A superregenerative receiver is described hereinafter. In the following description, numerous specific details, including circuit topologies, circuit components, component parameters, and the like are set forth. However, from this disclosure, it will be apparent to those skilled in the art that modifications and/or substitutions can be made without departing from the scope and spirit of the invention. In other circumstances, specific details can be omitted so as not to obscure the invention.

Where reference is made in any one or more of the accompanying drawings to steps and/or features, which have the same reference numerals, those steps and/or features have for the purposes of this description the same function(s) or operations(s), unless the contrary intention appears.

The embodiments of the invention improve the performance of conventional superregenerative receivers by providing high selectivity and optimum receiver sensitivity, which is insusceptible to variations in supply voltage, temperature and device parameters. In conventional designs, the quench oscillator provides intermittent biasing for the RF oscillator such that the RF oscillator alternates between oscillation and non-oscillation at the quench oscillator frequency. However, the performance of the receiver in such an arrangement becomes very sensitive to the external quench signal level as the DC operating point of the RF oscillator is biased directly by the quench voltage. Such dependency makes the sensitivity of the receiver prone to variations in supply voltage, temperature and device parameters.

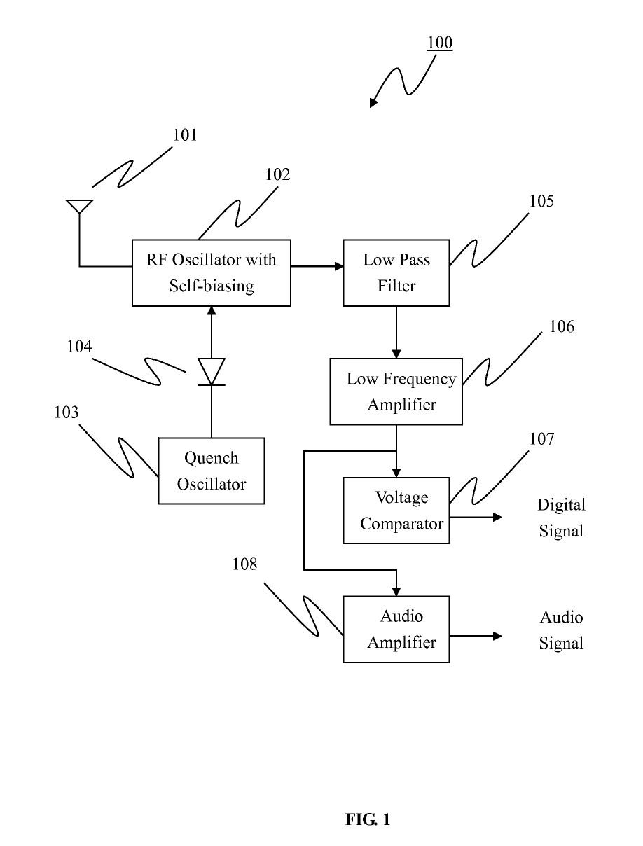

FIG. 1 shows a block diagram of a superregenerative receiver in accordance with a preferred embodiment of the present invention. The receiver 100 comprises an antenna 101 for converting RF energy into an electrical signal of radio frequency (RF). The RF signal is coupled to a RF oscillator 102. The RF oscillator 102 comprises a transistor with a self DC-biasing configuration for achieving stable operation point against variation in supply voltage, temperature and device parameters.

The superregenerative receiver 100 further comprises a quench oscillator 103 for generating a quench signal, which is a series of voltage pulses at the quench frequency. The quench signal is coupled to the RF oscillator 102 through a reversed-biased diode 104. The RF oscillator 102 starts oscillating at the positive pulse period of the quench signal as the quench signal is blocked by the reversed-biased diode 104. The RF oscillator 102 ceases to oscillate at the negative pulse period of the quench signal when such signal at the input of RF oscillator 102 is pulled to ground through the diode 104. Such a quenching mechanism allows the RF oscillator 102 to oscillate to a final operating point established by the DC self-biased configuration. The operating point is insensitive to variation of the absolute quench signal level, as long as the positive voltage pulse is greater than the voltage drop through the diode 104 plus the threshold voltage of the RF oscillator transistor 102 to reverse-bias diode 104.

The RF oscillator 102 outputs a signal composing of bursts of an RF carrier, which is coupled to a low pass filter 105 to filter off the RF carrier. The output of the low pass filter 105 is further amplified by a low frequency amplifier 106. The amplified signal can pass through a voltage comparator 107 and become a digital signal. Alternatively, the amplified signal can be further amplified by an audio amplifier 108 to provide an audio signal with the desired signal-to-noise ratio.

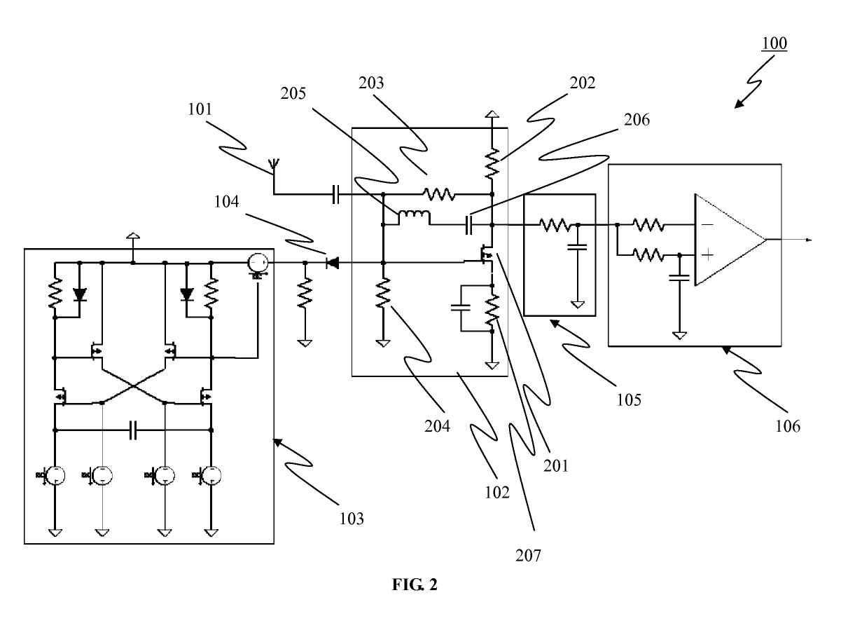

FIG. 2 shows the circuit of a superregenerative receiver according to the embodiment in FIG. 1. The RF oscillator 102 is DC self-biased for stable operating point and is quenched by a low-frequency quench signal. The quench signal is generated by a quench oscillator 103 and coupled to the RF oscillator 102 through a reversed-biased diode 104 (or diode-connected device from an FET or bipolar transistor). The cathode terminal of diode 104 is connected to the quench oscillator 103 and the anode terminal is connected to the RF oscillator 102. The quench signal generated at the output of quench oscillator 103 can be a series of current pulses. Such current pulses are then developed to a resistor to provide a quench signal of voltage pulses at the quench frequency. The voltage pulses have alternating zero voltage and a positive voltage greater than the voltage drop across the diode 104 (for example, 0.7V) plus one threshold voltage (for example, 0.7V) of the RF oscillator transistor 201.

In one embodiment in accordance with the invention, the RF oscillator 102 comprises a positive feedback circuit and a FET transistor 201 with self DC-biasing for stable operation point against temperature and device parameter variations. The DC operating current and voltage of the RF oscillator transistor 201 is set primarily by a drain loading resistor 202, the resistor divider comprising a drain-to-gate feedback resistor 203, a gate-to-ground resistor 204, a source-to-ground resistor 207 and the threshold voltage of the FET transistor 201 as shown in Equation 1:

I_{q}≈{V_{cc}×[R₂₀₄/(R₂₀₃+R₂₀₄)]−Vₜ}/{(R₂₀₄×R₂₀₂)/(R₂₀₃+R₂₀₄)+R₂₀₇} (1)

### Where

I_{q} is the DC operating current of the RF oscillator transistor 201;
Vₜ is the threshold voltage of the RF oscillator transistor 201; and
V_{cc} is the supply voltage.

The above parameters have very little dependency with device parameters and temperature changes. Accordingly, the configuration provides a stable operating point for the RF oscillator 201 against variation in device parameters and temperature. It is important to make sure that the RF oscillator settles to a well-defined operating point as the receiving sensitivity is directly proportional to the settled operating current.

In another embodiment in accordance with the invention, the RF oscillator transistor 201 is a bipolar transistor.

In a further embodiment in accordance with the invention, the positive feedback circuit comprises any lumped or distributed resonating networks or a SAW device to provide high frequency selectivity for the superregenerative receiver. The RF oscillator 102 shown in FIG. 2 is using a series lumped inductor-capacitor (LC) resonating network comprising inductor 205 and capacitor 206. Such network can be replaced by a SAW device having one terminal connected to the drain terminal of transistor 201 and the other terminal connected to the gate terminal of transistor 201.

### INDUSTRIAL APPLICABILITY

The embodiments and arrangements described hereinafter are applicable to electronics, integrated circuit, and wireless communication industries, amongst others.

The foregoing describes only a few preferred embodiments of the present invention, and modifications and/or substitutions can be made thereto without departing from the scope and spirit of the invention, the embodiments being illustrative and not restrictive.

I claim:

1. An oscillator circuit for a superregenerative receiver, comprising:
an RF oscillator, comprising a self-biased transistor and a positive feedback circuit; and
an external quench oscillator, for providing a quench signal to said RF oscillator;
wherein said quench signal is coupled to said RF oscillator through a reversed-biased diode.

2. An oscillator circuit for a superregenerative receiver according to claim 1, wherein said self-biased transistor is selected from the group consisting of a bipolar transistor and an FET transistor.

3. An oscillator circuit for a superregenerative receiver according to claim 1, wherein said positive feedback circuit of said RF oscillator comprises a lumped resonating network.

4. An oscillator circuit for a superregenerative receiver according to claim 1, wherein said positive feedback circuit of said RF oscillator comprises a distributed resonating network.

5. An oscillator circuit for a superregenerative receiver according to claim 1, wherein said positive feedback circuit of said RF oscillator comprises a surface acoustic wave (SAW) device.

6. A superregenerative receiver comprising:
an oscillator circuit, comprising
an RF oscillator comprising a self-biased transistor and a positive feedback circuit; and
an external quench oscillator for providing quench signal;
wherein said quench signal is coupled to said RF oscillator through a reversed-biased diode;
a low pass filter for filtering the output of said oscillator circuit; and
a low-frequency amplifier for amplifying the output of said low pass filter.

7. A superregenerative receiver according to claim 6, wherein said transistor is selected from the group consisting of a bipolar transistor and an FET transistor.

8. A superregenerative receiver according to claim 6, wherein said positive feedback circuit of said RF oscillator comprises a lumped resonating network.

9. A superregenerative receiver according to claim 6, wherein said positive feedback circuit of said RF oscillator comprises a distributed resonating network.

10. A superregenerative receiver according to claim 6, wherein said positive feedback circuit of said RF oscillator comprises a SAW device.

11. A superregenerative receiver according to claim 6, wherein the modulated RF signal from an antenna is coupled to said RF oscillator at any of the three terminals of said self-biased transistor.

12. A superregenerative receiver according to claim 6, further comprising a voltage comparator for comparing the output of said amplifier with a reference voltage to provide a demodulated digital signal.

13. A superregenerative receiver according to claim 6, further comprising an audio amplifier for amplifying the output of said low-frequency amplifier to provide a demodulated audio signal.

14. A method of detecting a modulated RF signal, said method comprising the steps of:
providing an external quench signal of low frequency;
providing an oscillator operating at a radio frequency, said oscillator comprising a self-biased transistor and a positive feedback circuit;
coupling said quench signal to said RF oscillator through a reversed-biased diode; and
coupling the modulated RF signal from an antenna to said RF oscillator at any of the three terminals of said self-biased transistor.

15. A method of detecting a modulated RF signal according to claim 14, further comprising the steps of:
low pass filtering the output of said RF oscillator to provide a filtered signal; and
amplifying the filtered signal to provide an amplified signal.

16. A method of detecting modulated RF signal according to claim 15, further comprising the step of comparing said amplified signal with a reference voltage to provide a demodulated digital signal.

17. A method of detecting modulated RF signal according to claim 15, further comprising the step of amplifying said amplified signal with an audio amplifier to provide a demodulated audio signal.
